(19) United States
(12) Patent Application Publication
(10) Pub. No.: US 2026/0271254 A1
(43) Pub. Date: Sep. 10, 2026

(54) BRIDGE BOARD REMOVAL TOOL

(71) Applicant: NVIDIA Corporation, Santa Clara, CA (US)

(72) Inventors: Aaron Ka Hoo Poon, San Marino, CA (US); Yunzhe Zhao, Quincy, MA (US); Mirui Wang, Milpitas, CA (US)

(21) Appl. No.: 19/550,908

(22) Filed: Feb. 26, 2026

Related U.S. Application Data
(63) Continuation-in-part of application No. 19/071,574, filed on Mar. 5, 2025.

(51) Int. Cl. H05K 13/00; H05K 7/14

(52) U.S. Cl. CPC H05K 13/0007; H05K 7/1489; H05K 7/1498; H05K 13/0015; H05K 13/0061

(57) ABSTRACT

An apparatus is described that includes a body having a pivot surface that extends along a first end of the body and a plurality of lever arms arranged linearly along the pivot surface and that project from the pivot surface such that a geometry of the pivot surface and the plurality of lever arms facilitate removal of a bridge board from a computing component assembly by causing at least one of the plurality of lever arms to contact an underside of the bridge board.

### CROSS-REFERENCE TO RELATED APPLICATIONS

This application is a continuation-in-part of U.S. Patent Application Serial No. 19/071,574, filed Mar. 5, 2025, which is currently pending and the entire disclosure of which is hereby incorporated herein by reference.

### BACKGROUND

Complicated integrated circuits such as central processing units and graphics processing units may be configured into chassis and rack systems (e.g., in enterprise server rooms and data centers) from which they interoperate for cooperative computing tasks such as artificial intelligence training and inference. These components may be organized within a chassis into circuit boards, and the circuit boards may be communicatively coupled to one another using bridge boards.

### GENERAL DESCRIPTION

Embodiments of the present disclosure contemplate improved tools and methods for removing a bridge board in a way that preserves the rest of the components organized within the server chassis.

In at least one embodiment, a tool is provided that includes: a body having a pivot surface; and a plurality of lever arms arranged linearly along the pivot surface, wherein each of the plurality of lever arms is formed such that the body forms an acute angle of engagement with a computing component assembly by contacting a structural surface of a component housing in which at least one circuit board is contained.

In some aspects, in a deployed configuration, (a) the pivot surface contacts a structural surface of the component housing, (b) a distal end of each of the plurality of lever arms contacts an underside of a bridge board mounted parallel to the structural surface of the component housing, and (c) an arc of each of the plurality of lever arms contacts an edge of the bridge board.

In some aspects, at least one of the plurality of lever arms extends from the pivot surface to a distal end and an interior angle between the at least one of the plurality of lever arms and the pivot surface is obtuse such that the body is configured to form an acute angle relative to the structural surface when the at least one of the plurality of lever arms is deployed.

In some aspects, at least one of the plurality of lever arms includes a distal end comprising a rectangular shape with a valley formed therein.

In some aspects, the body is formed such that a number of lever arms deployed from the body is configurable.

In some aspects, each of the plurality of lever arms are configured to extend from a corresponding slot in the body.

In some aspects, the body includes a tool body length, at least one lever arm in the plurality of lever arms includes a lever arm length, and the tool body length is at least twice the lever arm length.

In at least one other embodiment, an apparatus is provided that includes: a body including a pivot surface that extends along a first end of the body; and a plurality of lever arms arranged linearly along the pivot surface and that project from the pivot surface such that a geometry of the pivot surface and the plurality of lever arms facilitate removal of a bridge board from a computing component assembly by causing at least one of the plurality of lever arms to contact an underside of the bridge board.

In some aspects, the geometry of the pivot surface and the plurality of lever arms form an arc between the pivot surface and a distal end of each of the plurality of lever arms.

In some aspects, at least some of the plurality of lever arms are extendible from a corresponding slot formed in the body.

In some aspects, a number and positions of the plurality of lever arms are reconfigurable among a plurality of slots.

In some aspects, the plurality of lever arms include at least two lever arms.

In some aspects, the plurality of lever arms include at least four lever arms.

In some aspects, each of the plurality of lever arms include a distal end that physically contacts the underside of the bridge board.

In some aspects, the computing component assembly includes at least one component housing and the bridge board is provided over the at least one component housing.

In some aspects, each of the plurality of lever arms extend into gaps between adjacent component housings to access the underside of the bridge board.

In some aspects, the computing component assembly is provided in a chassis.

In some aspects, the pivot surface engages at least one component housing in the computing component assembly.

In some aspects, the plurality of lever arms apply an upward force to the bridge board in response to rotation of the body about the pivot surface.

In some aspects, each of the plurality of lever arms include a distal end having a rectangular shape with a valley formed therein.

In some aspects, the body includes a tool body length, at least one lever arm in the plurality of lever arms includes a lever arm length, and the tool body length is at least twice the lever arm length.

In at least one other embodiment, a bridge board removal process is provided that includes: (a) pivotably engaging a tool body with a structural surface of at least one component housing, where the tool body forms an acute angle relative to the structural surface; (b) inserting a plurality of lever arms into gaps between adjacent component housings to access an underside of the bridge board; and (c) contacting a distal end of the lever arms with the underside of the bridge board to urge the bridge board from the at least one component housing.

In some aspects, the tool body includes a tool body length, at least one lever arm in the plurality of lever arms includes a lever arm length, and the tool body length is at least twice the lever arm length.

In some aspects, the tool body includes a pivot surface that contacts at least one of the plurality of component housings and creates a leverage point where the pivot surface contacts the structural surface to enable the distal end to provide an upward force on the underside of the bridge board while preserving an integrity of a circuit board contained within the at least one component housing.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/implementations in combination with any one or more other aspects/features/implementations.

Use of any one or more of the aspects or features as disclosed herein.

It is to be appreciated that any feature described herein can be claimed in combination with any other feature(s) as described herein, regardless of whether the features come from the same described implementation.

The details of one or more aspects of the disclosure are set forth in the accompanying drawings and the description below. Other features, objects, and advantages of the techniques described in this disclosure will be apparent from the description and drawings, and from the claims.

Numerous additional features and advantages of the present disclosure will become apparent to those skilled in the art upon consideration of the implementation descriptions provided hereinbelow.

Additional features and advantages are described herein and will be apparent from the following description and the figures.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a server system in accordance with at least some embodiments.

FIG. 2 depicts a processing system in accordance with at least some embodiments.

FIG. 3 depicts a chassis including multiple circuit boards contained within and a bridge board in accordance with at least some embodiments.

FIG. 4 is a side view depiction of a bridge board utilized on a chassis in accordance with at least some embodiments.

FIG. 5 depicts a top perspective view of a bridge removal tool in accordance with at least some embodiments.

FIG. 6 depicts a top perspective view of a bridge removal tool in accordance with at least some embodiments.

FIG. 7 depicts a bottom perspective view of a bridge removal tool in accordance with at least some embodiments.

FIG. 8 depicts a bottom perspective view of a bridge removal tool in accordance with at least some embodiments.

FIG. 9 depicts a side view example of an embodiment of a bridge removal tool in a first deployment arrangement.

FIG. 10 depicts a side view example of an embodiment of a bridge removal tool in a second deployment arrangement.

FIG. 11 depicts a side view example of an embodiment of a bridge removal tool in a third deployment arrangement.

FIG. 12A depicts an example of a human user operating an embodiment of a bridge removal tool.

FIG. 12B depicts additional details of a bridge removal tool engaging a computing component assembly in accordance with at least some embodiments.

FIG. 13 depicts an example of a dual deployment arrangement of a bridge removal tool in accordance with at least some embodiments.

FIG. 14 provides a top view of a dual deployment arrangement of a bridge removal tool in accordance with at least some embodiments.

FIG. 15A depicts a side view of a bridge removal tool in accordance with at least some embodiments.

FIG. 15B depicts a perspective view of a bridge removal tool in accordance with at least some embodiments.

FIG. 15C depicts a front view of a bridge removal tool in accordance with at least some embodiments.

FIG. 16 depicts an exemplary computer system in accordance with at least some embodiments.

FIG. 17 depicts a parallel processing unit in accordance with at least some embodiments.

FIG. 18 illustrates an example data center in which a bridge removal tool may be used in accordance with at least some embodiments.

FIG. 19 illustrates components of a data center in accordance with at least some embodiments.

FIG. 20 illustrates two switches communicating with one another in a data center environment in accordance with at least some embodiments.

FIG. 21 illustrates a network device in accordance with at least some embodiments.

FIG. 22 illustrates a data center cooling system in accordance with at least some embodiments.

FIG. 23 illustrates a method of removing a bridge board from a server chassis in accordance with at least some embodiments.

### DETAILED DESCRIPTION

It can be difficult to remove a bridge board once it’s installed between the boards in a chassis due minimal clearance (e.g. 2.2mm) and lack of grip on the bridge board. Due to its low-profile form factor, and lack of clearance from the chips or packages upon which it is mounted, and the high forces needed for removal, removing a bridge board, such as an NVLink bridge board, may become very difficult for personnel. Mishandling risk is high when applying excessive and uneven force to remove the bridge board, which may damage the connectors and edge board gold fingers causing connectivity and signal integrity issues. This disclosure relates to a removal tool to disengage a bridge board coupling two or more integrated circuit chips or packages. The removal tool includes a handle and levers assembled onto the handle, the levers configured to set an angle of engagement enabling disengagement of the bridge board connectors from board edge fingers, whereby urging the handle, the bridge board disengages from the chips or packages. The levers are placed between boards comprising the chips or packages, and underneath the bridge board. With a simple press on the handle, the bridge board may be disengaged from the chips or packages so that the user can easily remove it. The removal tool has utility for example when servicing chips or packages such as graphics processing units (GPUs) or replacing faulty components, ensuring the bridge board can be safely removed.

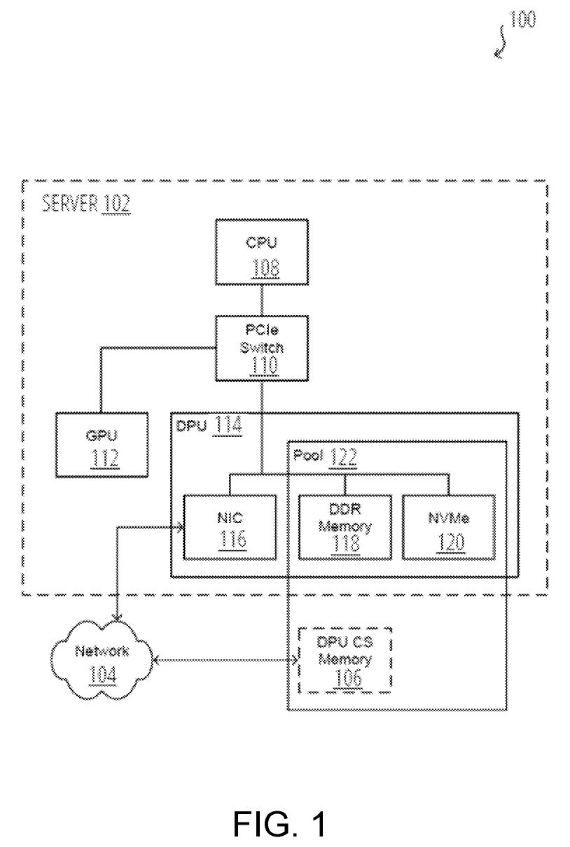

FIG. 1 depicts an example computing environment 100 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures.

The example computing environment 100 may include (one or more) server 102 which may be used to perform HPC workloads, such as AI training or machine learning model training. One or more of the servers may comprise a chassis and multiple processor boards coupled via a bridge board, as depicted and described more fully below. The removal of said bridge boards may utilize embodiments of the mechanisms disclosed herein. In an embodiment, the server 102 may be an application instance or a compute node. The server 102 may include a CPU 108 associated with a switch 110, such as a peripheral component interconnect express (PCIe) switch, which may control at least some data transmission over communication paths interconnecting various components. In an embodiment, the CPU 108 may include a root complex processor.

The PCIe switch 110 may also be associated with a GPU 112 and a DPU 114, and may transmit data between at least some of the CPU 108, the GPU 112, the DPU 114, and other components. In an embodiment, the PCIe switch 110 may be associated with more than one GPU or more than one DPU. In another embodiment, the PCIe switch 110 may be located within the DPU 114. The PCIe switch 110 may manage the transfer of at least some data between the CPU 108, the GPU 112, and the DPU 114. In another embodiment, the number of GPUs associated with the PCIe switch 110 may be equal to the number of DPUs associated with the PCIe switch 110. In at least one embodiment, the server 102 may include, without limitation, any number of the CPUs 108, the PCIe switches 110, the GPUs 112, and/or the DPUs 114, in any combination. For example, in at least one embodiment, server 102 could include eight, sixteen, thirty-two, and/or more GPUs 112.

In at least one embodiment, communication paths interconnecting various components, including but not limited to the CPU 108, the PCIe switch 110, the GPU 112, and the DPU 114, in FIG. 1 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 114 may include a network interface card (NIC) 116, a DDR memory 118, and a non-volatile memory express (NVMe) device 120. The NIC 116 may be able to interface with a network 104, which may also interface with additional NVMe devices available to the DPU 114, such as over fabric. In an embodiment, the DPU 114 may not include the NVMe device 120. In another embodiment, the NVMe device 120 may be located on the server 102 and not on the DPU 114.

In yet another embodiment, the computing environment 100 may include more than one of the NVMe device 120, such as a first NVMe device in the DPU 114 and a second NVMe device on the server 102 associated directly with the PCIe switch 110. In an embodiment, the DPU 114 may not include the DDR memory 118 and may include a computational storage services (CSS) in place of, or in addition to, the DDR memory 118. For example, computing environment 100 may include DPU computational storage (CS) memory 106 available to the DPU 114 as part of the CSS. The network 104 may be able to interface with the DPU CS memory 106 through the NIC 116, according to any suitable interface protocol, such as remote direct memory access (RDMA) over Ethernet, InfiniBand, Fiber Channel, etc..

The total memory of the computing environment 100 available for data storage may be expanded through the use of the DPU 114 on nodes of the system. The DPU 114 may have access to a pool 122 of memory already available to the server 102, such as double data rate (DDR) memory, on-board NVMe devices, NVMe devices over fabric, and CS. The pool 122 of memory may include at least one of the DDR memory 118, NVMe device 120, and the DPU CS memory 106.

The DPU 114 may also be able to access the available memory of other DPUs as part of the pool 122, and other DPUs may be able to access the available memory of DPU 114, such as the pool 122 . This available memory can be accessed and utilized for data storage, without the addition of compute resources, such as compute nodes, which would be required using other solutions.

The available pool 122 accessible to the DPU 114 may be provisioned for the server 102 to expand the total memory available for data storage, such as to reduce the data storage load on the CPU 108 or the GPU 112, which can instead increase the utilization of their memory for processing. For example, during training of an AI, the model states, residual states, activation functions, and checkpoints can be stored, or offloaded, on the pool 122 accessible to the DPU 114.

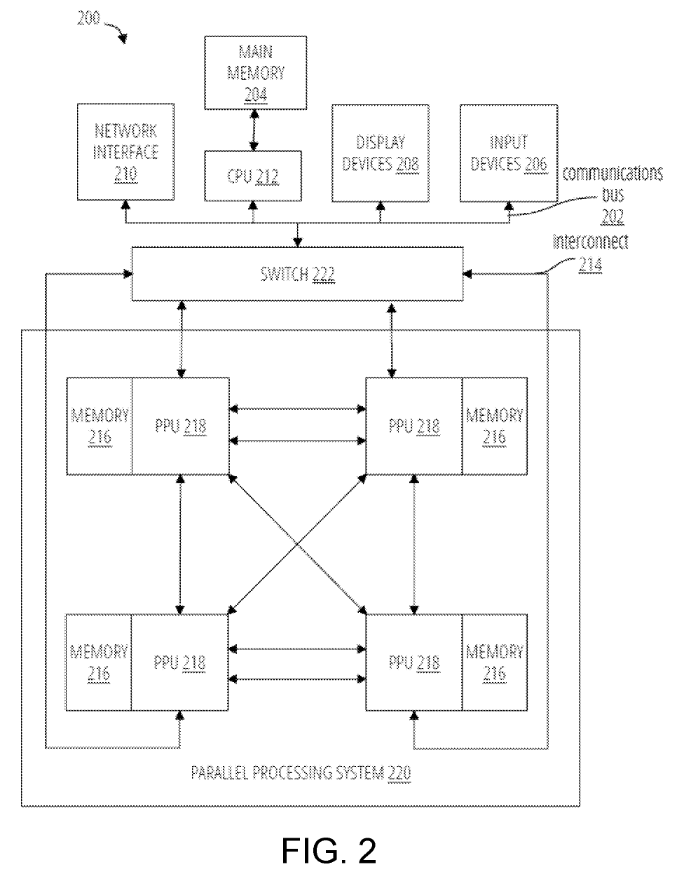

FIG. 2 depicts a computer system 200, according to at least one embodiment. In at least one embodiment, computer system 200 is configured with components such as multiple parallel processing units that utilize one or more bridge boards. The removal of said bridge boards may utilize embodiments of the mechanisms disclosed herein.

In at least one embodiment, computer system 200 comprises, without limitation, at least one central processing unit (“CPU”) 212 that is connected to a communications bus 202 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 200 includes, without limitation, a main memory 204 and control logic (e.g., implemented as hardware, software, or a combination thereof) and data are stored in main memory 204 which may take form of random-access memory (“RAM”). In at least one embodiment, a network interface subsystem (“network interface”) 210 provides an interface to other computing devices and networks for receiving data from and transmitting data to other systems from computer system 200.

In at least one embodiment, computer system 200 includes, without limitation, input devices 206, parallel processing system 220, and display devices 208 which can be implemented using a conventional cathode ray tube (“CRT”), liquid crystal display (“LCD”), light emitting diode (“LED”), plasma display, or other suitable display technologies. In at least one embodiment, user input is received from input devices 206 such as keyboard, mouse, touchpad, microphone, and more. In at least one embodiment, each of foregoing modules can be situated on a single semiconductor platform to form a processing system.

In at least one embodiment, computer programs in the form of machine-readable executable code or computer control logic algorithms are stored in main memory 204 and/or secondary storage. Computer programs, if executed by one or more processors, enable computer system 200 to perform various functions in accordance with at least one embodiment. Main memory 204, secondary storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 212; parallel processing system 220; an integrated circuit capable of at least a portion of capabilities of both CPU 212; parallel processing system 220; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 200 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 220 includes, without limitation, a plurality of parallel processing units (“PPUs”) 218 and associated memories 216. In at least one embodiment, PPUs 218 are connected to a host processor or other peripheral devices via an interconnect 214 and a switch 222 or multiplexer. In at least one embodiment, parallel processing system 220 distributes computational tasks across PPUs 218 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 218, although such shared memory may incur performance penalties relative to use of local memory and registers resident to a PPU 218. In at least one embodiment, operation of PPUs 218 is synchronized through use of a command such as_syncthreads (), wherein all threads in a block (e.g., executed across multiple PPUs 218 to reach a certain point of execution of code before proceeding.

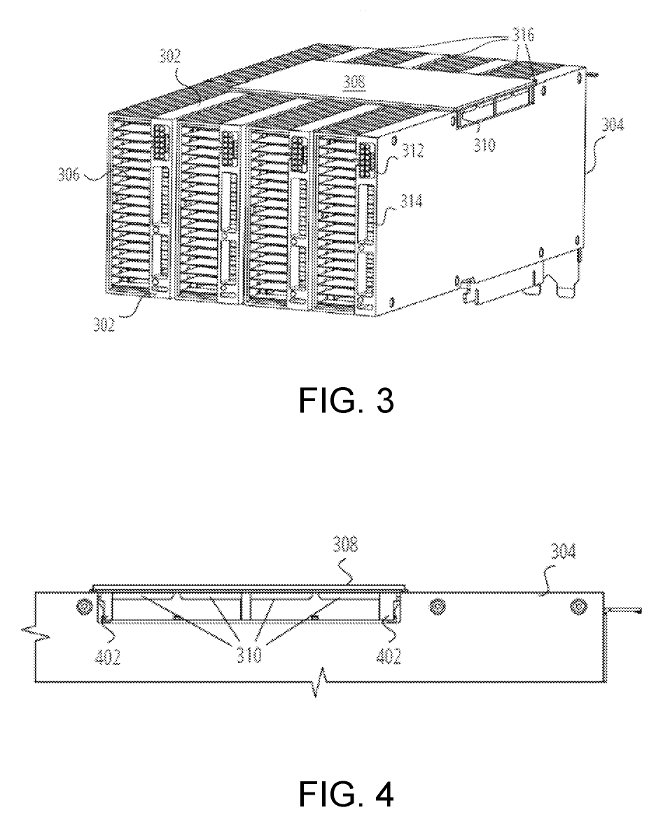

FIG. 3 depicts a chassis comprising multiple circuit boards contained within a computing component assembly 302, which may also include a component housing to protect the circuit board(s) contained therein. The chassis is further depicted to include a bridge board 308 spanning at least two of the computing component assemblies 302 in accordance with at least some embodiments. The chassis may be utilized for example in systems in accordance with FIGS. 1 and 2 or in any other computing environment depicted and described herein. Multiple computing component assemblies 302, which may include one or multiple circuit boards, are configured into a chassis, and there may be multiple chassis configured into a rack system, for example in a data center or enterprise server room. By way of example, the computing component assemblies 302 may each comprise one or more graphics processing unit (GPU), central processing unit (CPU), and combinations thereof, and may include complementary circuitry and logic therefor such as power modules, temperature control logic, memory, and so on. The computing component assembly 302 may further include at least one component housing that provides one or multiple protective structures for the elements contained therein. In one example, the computing component assemblies 302 may include central processing units (CPUs), graphics processing units (GPUs), data processing units (DPUs), quantum processing units (QPUs), a plurality of parallel processing units (PPUs), and application-specific integrated circuits (ASICs). QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

The depicted chassis comprises a dual-slot configuration of four circuit boards, where each circuit board is contained within a corresponding component housing of a computing component assembly 302. In general, the chassis may comprise any number of computing component assemblies 302, each of which may be configured similarly or differently with one or multiple circuit boards in different sizes and configurations, such as single-slot boards, dual-slot boards, triple-slot boards, and combinations of boards of different sizes.

Each computing component assembly 302 may include associated cooling fins 306 to dissipate heat, vents 314, and power ports 312. The computing component assembly 302 or the circuit boards contained therein may be coupled via a bridge board 308 comprising connectors 310 aligned with input/output pins of the circuity on the boards. The bridge board 308 may be any suitable high-speed interconnect. Example host attachment technologies include compute express link (CXL) as part of PCI-5.0 spec, NVLink (used for GPUs), cache coherent interconnect for accelerators (CCIX) used for ARM processors, and OpenCAPI (open coherent accelerator processor interface). The bridge board 308 is mounted parallel to a surface of the component housing 304. In one embodiment, the bridge board 308 may comprise a number of connectors 310 for each circuit board in a computing component assembly 302 equal to the number of boards in the chassis (e.g., four connectors per board for the four-board configuration depicted, two connectors per board for a two-board configuration, eight connectors per board for an eight-board configuration). In a particular embodiment in which each board comprises one graphics processing unit, each connector 310 may comprise 256 pins. The bridge board 308 may comprise logic such as metal paths, optical paths, and switching fabrics to enable signaling between the boards.

In the example depicted in FIG. 3, the bridge board 308 bridges all of the circuit boards in the chassis. In other embodiments, a particular bridge board 308 may bridge less than all of the circuit boards in the chassis, meaning that the bridge board 308 may span less than all of the corresponding computing component assemblies 302 of the chassis. For example, a chassis comprising four circuit boards may utilize two bridge boards 308, each bridging only two of the four circuit boards.

A bridge removal tool may engage with one or more portions of the computing component assembly 302 to help remove a bridge board 308 from the one or more circuit boards. In some embodiments, the bridge removal tool may interface with a structural surface of a component housing in which a circuit board is contained. For instance, each computing component assembly 302 may include at least one circuit board and at least one component housing for each circuit board. A component housing may include a structural element, such as a shroud, cover, frame, or the like that partially or completely contains a circuit board

A body 510 of the bridge removal tool may contact the structural element(s) that protect the board and then one or more lever arms 512 may extend into one or more corresponding gaps 316, including a gap at an edge of the bridge board 308 where it protrudes slightly beyond an extent of the chassis. As discussed in further detail herein, the one or more lever arms 512 may extend into the gap(s) 316 between adjacent computing component assemblies 302 and then contact an underside of the bridge board 308 to help remove the bridge board 308 from the component housing 304 without damaging circuit boards contained within the component housings 304 of the computing component assemblies 302.

FIG. 4 is a side view depiction of a bridge board 308 utilized on a component housing 304 in accordance with one embodiment. FIG. 4 depicts the connectors 310 of the bridge board 308 in additional aspects, and also depicts retaining mechanisms 402 (e.g., clips or clamps) that may be utilized to stabilize the bridge board 308 in relation to the component housing 304.

In one embodiment, the connector 310 are configured to interface with pins of PCIe interfaces to circuity on the boards. PCIe, or Peripheral Component Interconnect Express, is a high-speed interface commonly utilized to connect various components and peripherals in computer systems. PCIe is commonly utilized for connecting graphics boards, solid-state disks, network cards, and other expansion boards to the system. PCIe comprises a point-to-point architecture, enabling direct data links between devices and a data processor for example, resulting in higher transfer rates compared to earlier interface standards.

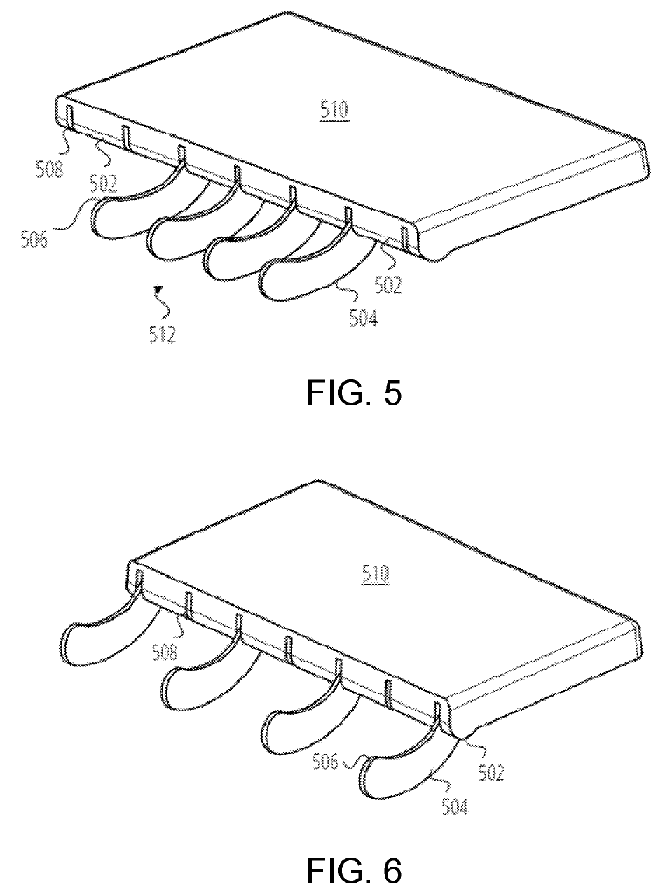

FIG. 5 depicts a top perspective view of a bridge removal tool in accordance with one embodiment. The bridge removal tool is shown to include a body 510 comprising multiple slots 508 along a side of the body 510. A set of (e.g., four) adjacent slots 508 are configured with lever arms 512 each comprising an arc or hook 504 and a distal end 506 (distal from the body 510/slots 508). The lever arms 512 may be formed for example from metal or extruded or molded plastic, although plastic may be preferred as being less likely to damage the bridge board 308 during removal. The body 510 may also for example be formed from (extruded or molded) plastic, or metal. The body 510, in some embodiments, serves as a handle for operating the bridge removal tool.

The body 510 may comprise more slots 508 than lever arms 512, so that the bridge removal tool may be reconfigured with lever arms 512 in different positions and/or with different numbers of lever arms 512. Herein, ‘adjacent slots’ refers to two slots that are not separated from one another by one or more intervening slot.

The body 510 is further formed with a pivot surface 502. The body 510, pivot surface 502, and lever arms 512 may be cooperatively utilized to disengage a bridge board 308 from multiple boards contained within corresponding component housings of computing component assemblies 302 in manners described below. As an example, the lever arms 512 may project from the pivot surface 502 such that a geometry of the pivot surface 502 and the lever arms 512 facilitate removal of the bridge board 308 from a computing component assembly 302 by causing at least one of the lever arms 512 to contact an underside of the bridge board 308. It should be appreciated that the computing component assembly 302 from which the bridge board 308 is removed may include a plurality of computing component assemblies 302 arranged within the chassis. In some embodiments, a pair of adjacent computing component assemblies 302 (or component housings thereof) may have a gap 316 therebetween. The lever arms 512 may be capable of extending into the gaps 316 between adjacent computing component assemblies 302 to access the underside of the bridge board 308. The pivot surface 502 may be configured to engage a structural surface of at least one of the computing component assemblies 302 such that the rotation of the body 510 about the pivot surface 502 while the pivot surface 502 is engaged with the structural surface of a component housing enables the lever arms 512 to contact the underside of the bridge board 308 and apply an upward force thereto, which urges the bridge board 308 away from the rest of the computing component assembly. The configuration of the bridge removal tool depicted in FIG. 5 may be utilized with a single-slot configuration of multiple circuit boards. The number of lever arms 512 and their slot locations may be configured to suit a particular configuration of circuit boards and board sizes in a given chassis.

FIG. 6 depicts a top perspective view of a bridge removal tool in accordance with another embodiment. The configuration of the bridge removal tool depicted in FIG. 6 may be utilized with a dual-slot configuration of multiple circuit boards (hence the additional spacing between the lever arms 512). In this configuration the lever arms 512 are mounted in alternate slots 508, meaning that there is one empty slot separating the slots with lever arms mounted in them. A dual-slot configuration may accommodate up to 88 boards, doubling the number of available GPUs compared to the single-slot configuration.

As with the single-slot configuration depicted in FIG. 5, the number of lever arms 512 and their slot locations may be configured to suit a particular configuration of circuit boards and board sizes in a given chassis. For example, the lever arms 512 of the bridge removal tool may be configured to remove a bridge board 308 from a chassis comprising a non-uniform arrangement of bridged single-slot and dual-slot circuit boards.

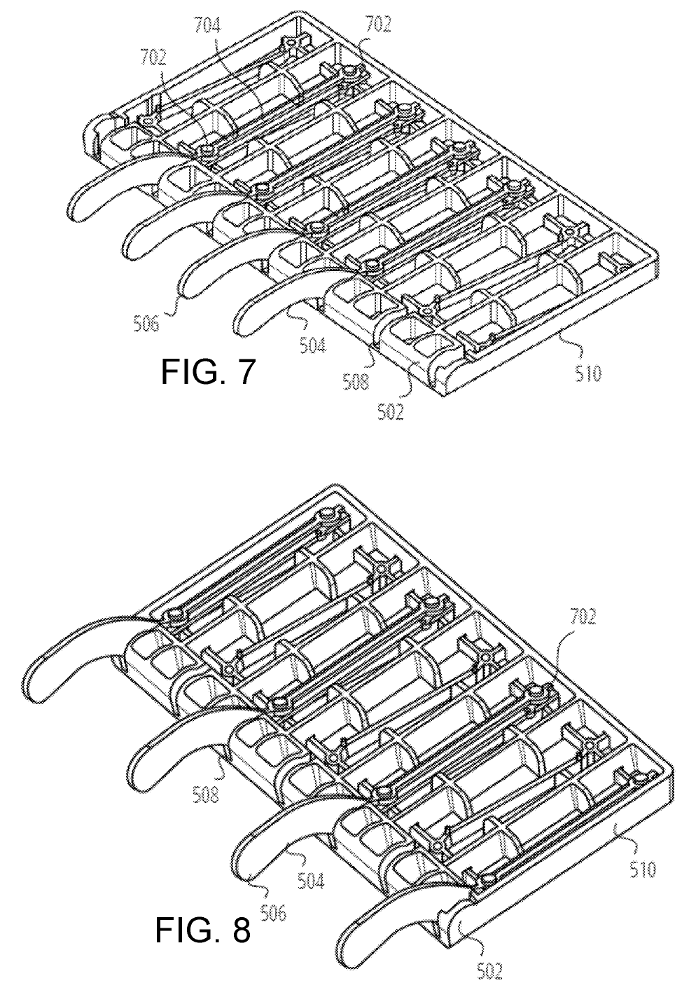

FIG. 7 depicts a bottom perspective view of a bridge removal tool in accordance with the single-slot compatible embodiment depicted in FIG. 5. The bridge removal tool is highly configurable for different bridging configurations. A lever arm 512 may be added to or removed from any slot 508 via the installation or removal of a rigid coupler 704 (e.g., a plastic or metal rod) secured with common retaining mechanisms 702 such as screws, bolts, or pins. In one embodiment, the lever arms 512 and the rigid coupler 704 are formed as a single piece of molded (e.g., extruded) heavy-duty plastic.

FIG. 8 depicts a bottom perspective view of a bridge removal tool in accordance with the dual-slot compatible embodiment depicted in FIG. 6.

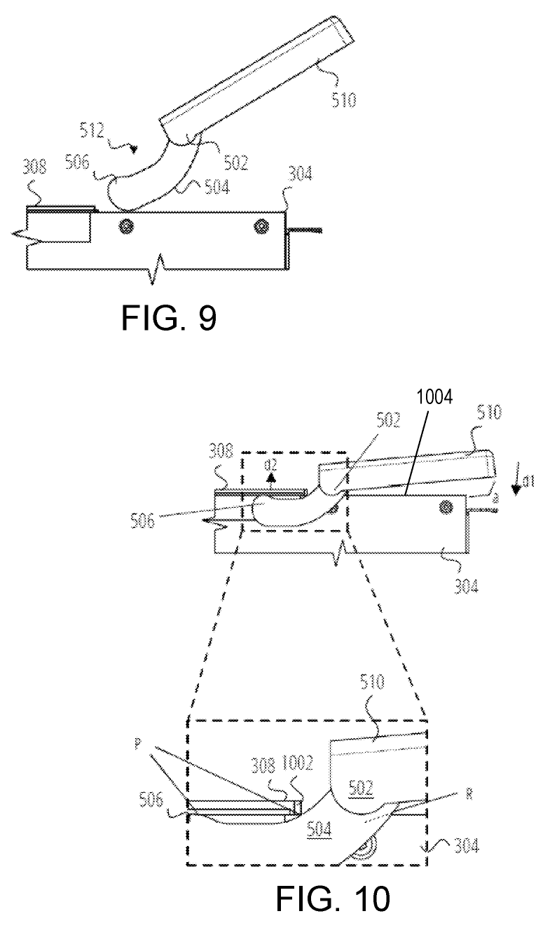

FIG. 9 depicts a side view of an embodiment of a bridge removal tool in a first deployed arrangement. Only one of the lever arms 512 is depicted, this being the lever arm 512 that engages with a gap at an edge of the bridge board 308 where it protrudes slightly beyond an extent of the chassis.

FIG. 10 depicts a view of the bridge removal tool of FIG. 9 in a second deployed arrangement. The points P indicate points of contact between the lever arm 512 and the bridge board 308. Contact is made between the distal end 506 of the lever arm 512 and the bridge board 308, and between an edge of the bridge board 308 and a point along the arc 504 of the lever arm 512. The pivot surface 502 of the body 510 also contacts a structural surface 1004 of the computing component assembly 302 (at a point R behind the one depicted lever arm 512), acting as a fulcrum.

In the deployed arrangement of FIG. 10, the body 510 is at an angle a with the top surface of the component housing 304. This angle may correspond to an acute interior angle and may, for example, be between 5 and 30 degrees. From this angle of engagement, the body 510 may be urged along an approximate vector d1, with components both toward the component housing 304 and toward the bridge board 308. Urging the body 510 along vector d1 may instill a force on the bridge board 308 along vector d2, away from the component housing 304. The urging of the bridge board 308 along vector d2 is facilitated by engagement of the radius of the arc/hook 504 with the edge of the bridge board 308. This latter engagement facilitates initial unlatching of the connectors on the bridge board 308 from gold fingers of the underlying chip or package, and helps prevent damage to the bridge board 308, connectors 310, or underlying chips or packages contained in the computing component assembly 302 during removal of the bridge board 308. It should be appreciated that the radius of the arc/hook 504 may be configured to engage with the edge of the bridge board 308 to help facilitate this smooth and safe initial unlatching of the bridge board 308 therefrom.

The bridge removal tool may thus comprise lever arms 512 arranged linearly along the pivot surface 502 of the body 510, each lever arm 512 comprising an arc 504 and a distal end 506. The lever arms 512 are inserted into gaps 316 at the edge 1002 of the bridge board 308, and the arcs 504 of the lever arms 512 are formed such that the body 510 of the bridge removal tool forms a shallow angle (between five and thirty degrees) with the component housing 304 when the pivot surface 502 contacts the component housing 304, and the distal ends 506 of the lever arms 512 contact an underside 1104 of the bridge board 308, and the arcs 504 contact the edge 1002 of the bridge board 308. Herein, the ‘underside’ surface 1104 of the bridge board 308 may refer to the surface of the bridge board 308 adjacent to or facing the structural surface 1004 of the computing component assembly 302 that faces outward relative to the rest of the component housing 304. The angle may be configured just sufficiently to disengage the connectors 310 of the bridge board 308 from the edge gold fingers of the circuit boards. With a simple rotational force applied at the pivot surface 502, the bridge board 308 may disengage from the underlying chips or packages so that the user can easily remove it.

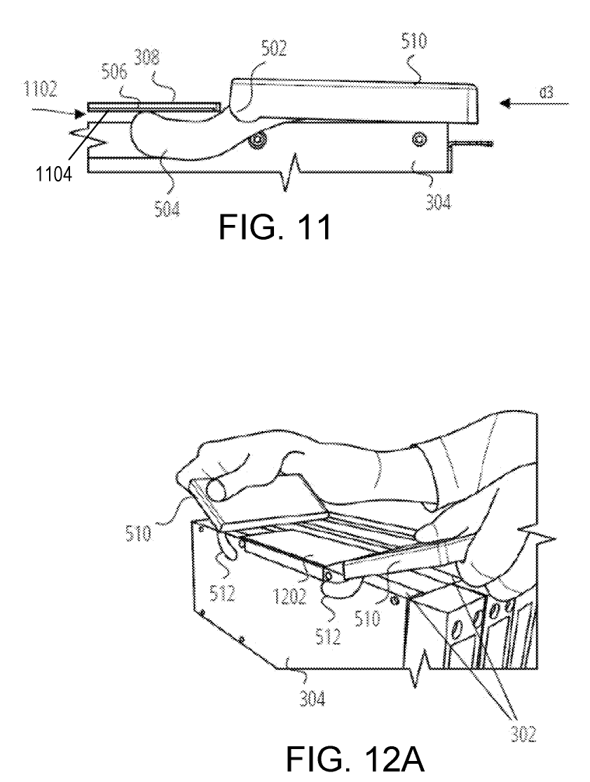

FIG. 11 depicts an example of an embodiment of a bridge removal tool in a third deployed arrangement. The body 510 has been urged into contact with the component housing 304 and toward the bridge board 308 along vector d3, disengaging the connectors 310 of the bridge board 308 from the corresponding ports (e.g., PCIe) on the circuit boards and forming a separation 1102 between the bridge board 308 and the component housing 304. The separation 1102 may also corresponding to a measurable distance between the underside 1104 of the bridge board 308 and the structural surface 1004 of the computing component assembly 302.

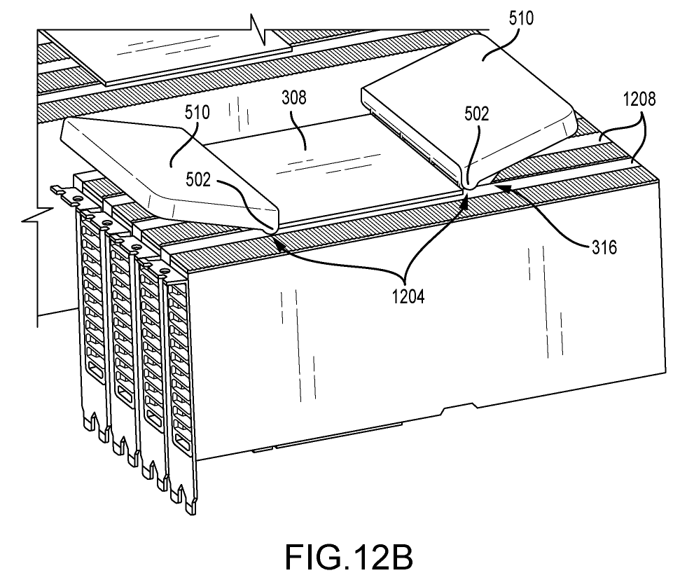

FIGS. 12A and 12B illustrate additional details of a bridge removal tool. In an example, FIG. 12A depicts an example of a human user operating an embodiment of a bridge removal tool. Unlike the bridge board 308 depicted in prior drawings, the bridge board 1202 depicted in FIG. 12A spans and bridges two boards in the chassis, instead of four.

To remove the bridge board 1202, the human user employs a pair of bridge removal tools, one in each hand. The lever arms 512 of the bridge removal tools are engaged with the bridge board 1202 at both (e.g., opposite) ends and operated as described in conjunction with FIGS. 9-11 to create a separation 1102 between the bridge board 1202 and the component housing 304. Once the separation 1102 is established, the human user may use their hands to complete the removal of the bridge board 1202 from the computing component assemblies 302. The tool may be pressed downward and toward the board until bottoms-up to the underlying connector.

Specifically, as shown in FIG. 12B, each bridge removal tool may be brought into contact with one or more structural surfaces 1004 of one or more component housings 1208. Each component housing 1208 may be a part of a corresponding computing component assembly 302 in which one or more circuit boards are contained. The bridge removal tool may be positioned such that the pivot surface 502 of the body 510 contacts a structural surface 1004 of a component housing 1208. The pivot surface 502 may contact the component housing 1208 at a contact point 1204 while the lever arms 512 extend into gaps 316 between adjacent computing component assemblies 302. In some embodiments, each lever arm 512 is arranged linearly along the pivot surface 502 and projects from the pivot surface 502 such that a geometry of the pivot surface 502 and the lever arm 512 facilitate removal of a bridge board 308 from a computing component assembly 302 by causing at least one of the plurality of lever arms 512 to contact the underside 1104 of the bridge board 308.

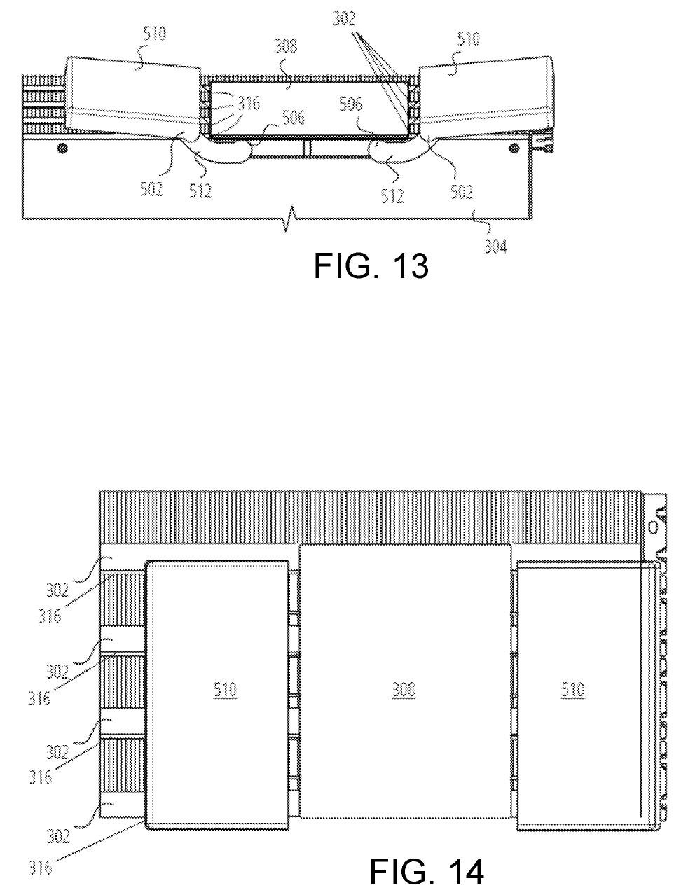

FIG. 13 and FIG. 14 depict an example of a dual deployment of a bridge removal tool in one aspect. A bridge removal tool is deployed on each of two sides of the bridge board 308 in the initial configuration depicted in FIG. 9. The lever arms 512 are inserted into gaps 316 between computing component assemblies 302 and the distal ends 506 of the lever arms 512 are engaged with the underside 1104 of the bridge board 308. The body 510 of the bridge removal tool is angled (e.g., 5 to 30 degrees) in relation to the component housing 304.

The dual deployment configuration may not be required for removing the bridge board in every circumstance. However, the dual deployment configuration may be advantageous over use of a single bridge removal tool because it may lessen the chances of damaging the bridge board and/or the connectors on the boards.

Once deployed in the initial configuration of FIG. 9, both bridge removal tools may each be operated together as described in conjunction with FIGS. 10 and 11 to create the separation 1102 at both ends of the bridge board 308.

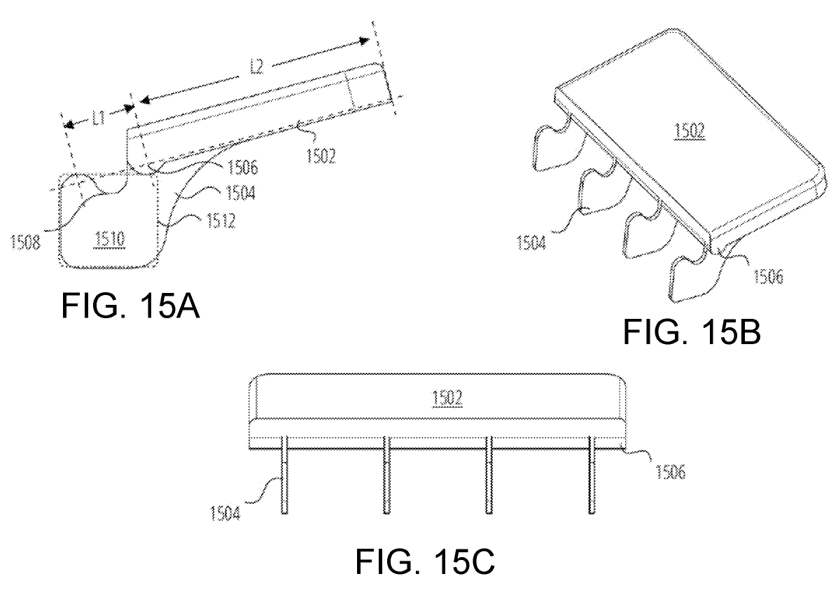

FIGS. 15A-15C depict a side, perspective, and front view of a bridge removal tool in accordance with another embodiment. This embodiment may be formed as a single piece, e.g., as molded or extruded plastic, obviating the need for assembling parts together. This embodiment may be operated to disengage a bridge board from computing component assemblies 302 using the process depicted in FIGS. 9-14.

The bridge removal tool is shown to include a body 1502 with an integral pivot surface 1506, and a plurality of lever arms 1504 each with a distal end 1510 comprising a rectangular bulk shape 1512 with a depression/valley 1508 formed in it. The rectangular bulk shape 1512 may contain more than 50% of the material of the lever arm 1504, thereby providing an increased structural integrity to the lever arm 1504. The lever arms 1504 and the body 1502 may be molded as a single piece. Depending on the configuration of the component housings in the chassis system, the bridge removal tool may be formed to have different numbers of the lever arms 1504 in different configurations, as previous described in conjunction with other embodiments. To provide sufficient levering force, the L2 extent of the body 1502 from the pivot surface 1506 (depicted in FIG. 15A) may be proportioned at least twice the L1 extent of the rectangular bulk shape 1512 from the pivot surface 1506. Such a configuration of a lever arm and body (e.g., where L2 is at least two times larger than L1) may also be utilized for examples of the bridge removal tool depicted and described herein.

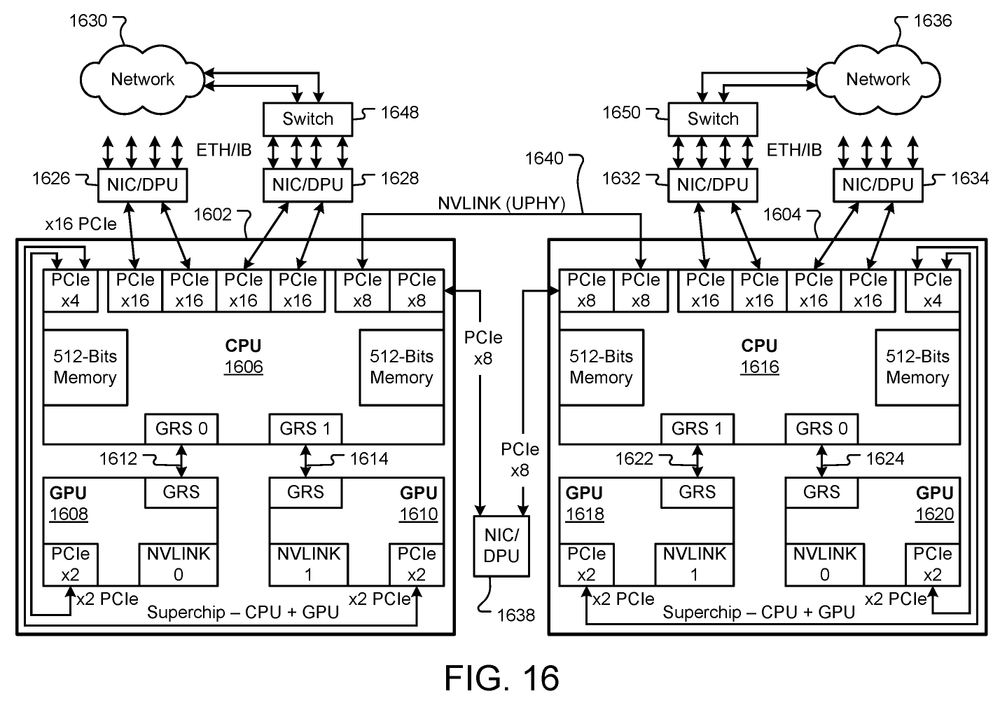

FIG. 16 depicts a block diagram that schematically illustrates a computing system 1600, e.g., a data center or a High-Performance Computing (HPC) cluster, in accordance with an embodiment that is described herein. The computing system 1600 comprises a plurality of subsystems, e.g. multiple processing devices coupled to each other, multiple network devices, and multiple networks, according to at least one embodiment. Computing system 1600 is designed with multiple integrated circuits (referred to as processing devices), where each integrated circuit can include one or more CPUs and GPUs, forming a powerful and flexible architecture. In some configurations, the sub-systems and/or the CPUs/GPUs of computing system 1600 may be implemented on circuit boards coupled via one or more bridge boards, which may be contained within one or more component housings. The removal of said bridge boards may utilize embodiments of the mechanisms disclosed herein.

The various processing devices are interconnected via an NVLink or other high-speed interconnect, enabling high-speed communication between the subsystems, and are also connected through a NIC or DPU (Data Processing Unit) to ensure efficient data transfer across computing system 1600 and to one or more external networks 1630, 1636. In the present example, system 1600 comprises a packet switch 1642 that connects NIC/DPU 1628 to network 1630, and a packet switch 1644 that connects NIC/DPU 1632 to network 1636.

The coupling of processing devices through NVLink allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1600 can include one or more CPUs and one or more GPUs.

FIG. 16 also depicts an example of a multi-GPU architecture. As depicted, computing system 1600 includes a processing device 1602 with a multi-GPU architecture. In particular, processing device 1602 may be a system-on-chip that includes multiple subsystems such as a CPU 1606, a GPU 1608, and a GPU 1610. CPU 1606 can be coupled to GPU 1608 via a die-to-die (D2D) or chip-to-chip (C2C) interconnect 1612, such as a Ground-Referenced Signaling interconnect (GRS interconnect). CPU 1606 can be coupled to GPU 1610 via a D2D or C2C interconnect 1614. CPU 1606 can also couple to GPU 1608 and GPU 1610 via PCIe interconnects.

CPU 1606 can be coupled to one or more NICs or DPUs, which are coupled to one or more networks. For example, as depicted in FIG. 16, CPU 1606 is coupled to a first NIC/DPU 1626, which is coupled to a network 1630. CPU 1606 is also coupled to a second NIC/DPU 1628, which is coupled to network 1630 via switch 1642. NIC/DPU 1626 and NIC/DPU 1628 can be coupled to network 1630 over Ethernet (ETH), NVLINK or InfiniBand (IB) connections, for example.

Computing system 1600 also includes a processing device 1604 with a multi-GPU architecture. In particular, processing device 1604 includes multiple subsystems including a CPU 1616, a GPU 1618, and a GPU 1620. CPU 1616 can be coupled to GPU 1618 via an D2D or C2C interconnect 1622. CPU 1616 can be coupled to GPU 1620 via a D2D or C2C interconnect 1624. CPU 1616 can also couple to GPU 1618 and GPU 1620 via PCIe interconnects. CPU 1616 can be coupled to one or more NICs or DPUs, which are coupled to one or more networks. For example, as illustrated in FIG. 16, CPU 1616 is coupled to a first NIC/DPU 1632, which is coupled to a network 1636. CPU 1616 is also coupled to a second NIC/DPU 1634, which is coupled to network 1636 via switch 1644. NIC/DPU 1632 and NIC/DPU 1634 can be coupled to network 1636 over Ethernet (ETH), NVLINK or InfiniBand (IB) connections.

In at least one embodiment, processing device 1602 and processing device 1604 may communicate with each other via a NIC/DPU 1638, such as over PCIe interconnects. Processing device 1602 and processing device 1604 may also communicate with each other over a high-bandwidth communication interconnects 1640, such as an NVLink interconnect or other high-speed interconnects. The packet switches in FIG. 16 may comprise, for example, Nvidia Quantum-2 switches. The NICs/DPUs in the figure may comprise, for example, Nvidia Bluefield DPUs.

Computing devices utilizing one or more graphic processing unit (GPU) and/or general purpose data processor (e.g., a 'central processing unit or CPU) may be configured with bridge boards, the removal of which may utilize embodiments of the mechanisms disclosed herein. Exemplary architectures will now be described that may be configured to implement the mechanisms disclosed herein.

The following description may use certain acronyms and abbreviations as follows:

"DPC" refers to a "data processing cluster";

"GPC" refers to a "general processing cluster";

"I/O" refers to a "input/output";

"L1 cache" refers to "level one cache";

"L2 cache" refers to "level two cache";

"LSU" refers to a "load/store unit";

"MMU" refers to a "memory management unit";

"MPC" refers to an "M-pipe controller";

"PPU" refers to a "parallel processing unit";

"PROP" refers to a "pre-raster operations unit";

"ROP" refers to a "raster operations";

"SFU" refers to a "special function unit";

"SM" refers to a "streaming multiprocessor";

"Viewport SCC" refers to "viewport scale, cull, and clip";

"WDX" refers to a "work distribution crossbar"; and

"XBar" refers to a "crossbar".

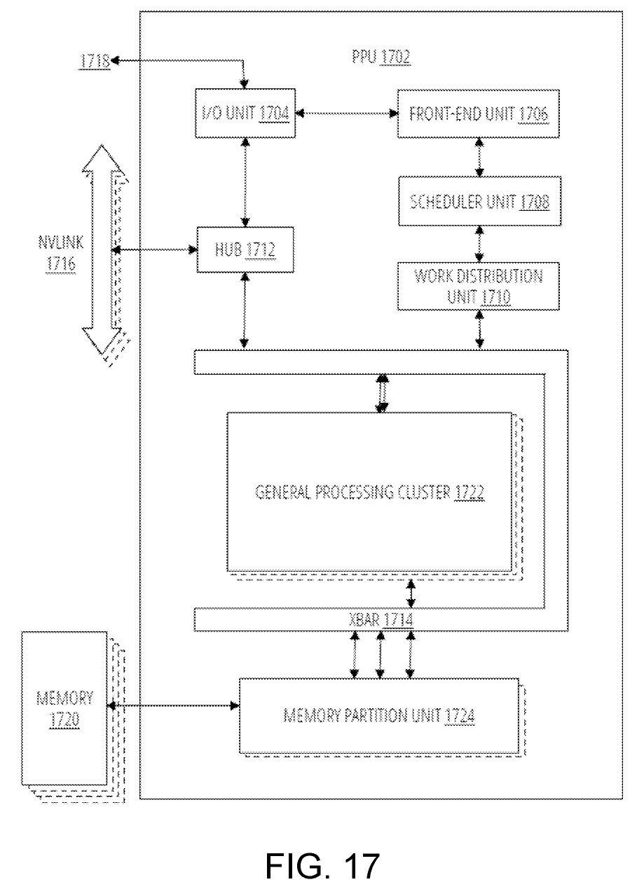

FIG. 17 depicts a parallel processing unit 1702, in accordance with an embodiment. In an embodiment, the parallel processing unit 1702 is a multi-threaded processor that is implemented on one or more integrated circuit devices. The parallel processing unit 1702 is a latency hiding architecture designed to process many threads in parallel. A thread (e.g., a thread of execution) is an instantiation of a set of instructions configured to be executed by the parallel processing unit 1702. In an embodiment, the parallel processing unit 1702 is a graphics processing unit (GPU) configured to implement a graphics rendering pipeline for processing three-dimensional (3D) graphics data in order to generate two-dimensional (2D) image data for display on a display device such as a liquid crystal display (LCD) device, an organic light emitting diode (OLED) device, a transparent light emitting diode (TOLED) device, a field emission display (FEDs), a field sequential display, a projection display, a head mounted display or any other desired display. In other embodiments, the parallel processing unit 1702 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

For example, one or more parallel processing unit 1702 modules may be configured to accelerate thousands of High Performance Computing (HPC), data center, and machine learning applications. The parallel processing unit 1702 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

The parallel processing unit 1702 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 1702 is embodied on a single semiconductor substrate. In another embodiment, the parallel processing unit 1702 is included in a system-on-a-chip (SoC) along with one or more other devices such as additional parallel processing units 1702, the memory 1720, a reduced instruction set computer (RISC) CPU, a memory management unit (MMU), a digital-to-analog converter (DAC), and the like.

In an embodiment, the parallel processing unit 1702 may be included on a graphics board that includes one or more memory devices 1720. The graphics board may be configured to interface with a PCIe slot on a motherboard of a desktop computer. In yet another embodiment, the parallel processing unit 1702 may be an integrated graphics processing unit (iGPU) or parallel processor included in the chipset of the motherboard.

As shown in FIG. 17, the parallel processing unit 1702 includes an I/O unit 1704, a front-end unit 1706, a scheduler unit 1708, a work distribution unit 1710, a hub 1712, a crossbar 1714, one or more general processing clusters 1722, and one or more memory partition units 1724. The parallel processing unit 1702 may be connected to a host processor or other parallel processing unit 1702 modules via one or more high-speed NVLink 1716 interconnects. The parallel processing unit 1702 may be connected to a host processor or other peripheral devices via an interconnect 1718. The parallel processing unit 1702 may also be connected to a local memory comprising a number of memory 1720 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 1720 may comprise logic to configure the parallel processing unit 1702 to carry out aspects of the techniques disclosed herein.

The NVLink 1716 interconnect enables systems to scale and include one or more parallel processing unit 1702 modules combined with one or more CPUs, supports cache coherence between the parallel processing unit 1702 modules and CPUs, and CPU mastering. Data and/or commands may be transmitted by the NVLink 1716 through the hub 1712 to/from other units of the parallel processing unit 1702 such as one or more copy engines, a video encoder, a video decoder, a power management unit, etc. (not explicitly shown).

The I/O unit 1704 is configured to transmit and receive communications (e.g., commands, data, etc.) from a host processor (not shown) over the interconnect 1718. The I/O unit 1704 may communicate with the host processor directly via the interconnect 1718 or through one or more intermediate devices such as a memory bridge. In an embodiment, the I/O unit 1704 may communicate with one or more other processors, such as one or more parallel processing unit 1702 modules via the interconnect 1718. In an embodiment, the I/O unit 1704 implements a Peripheral Component Interconnect Express (PCIe) interface for communications over a PCIe bus and the interconnect 1718 is a PCIe bus. In alternative embodiments, the I/O unit 1704 may implement other types of well-known interfaces for communicating with external devices.

The I/O unit 1704 decodes packets received via the interconnect 1718. In an embodiment, the packets represent commands configured to cause the parallel processing unit 1702 to perform various operations. The I/O unit 1704 transmits the decoded commands to various other units of the parallel processing unit 1702 as the commands may specify. For example, some commands may be transmitted to the front-end unit 1706. Other commands may be transmitted to the hub 1712 or other units of the parallel processing unit 1702 such as one or more copy engines, a video encoder, a video decoder, a power management unit, etc. (not explicitly shown). In other words, the I/O unit 1704 is configured to route communications between and among the various logical units of the parallel processing unit 1702.

In an embodiment, a program executed by the host processor encodes a command stream in a buffer that provides workloads to the parallel processing unit 1702 for processing. A workload may comprise several instructions and data to be processed by those instructions. The buffer is a region in a memory that is accessible (e.g., read/write) by both the host processor and the parallel processing unit 1702. For example, the I/O unit 1704 may be configured to access the buffer in a system memory connected to the interconnect 1718 via memory requests transmitted over the interconnect 1718. In an embodiment, the host processor writes the command stream to the buffer and then transmits a pointer to the start of the command stream to the parallel processing unit 1702. The front-end unit 1706 receives pointers to one or more command streams. The front-end unit 1706 manages the one or more streams, reading commands from the streams and forwarding commands to the various units of the parallel processing unit 1702.

The front-end unit 1706 is coupled to a scheduler unit 1708 that configures the various general processing clusters 1722 to process tasks defined by the one or more streams. The scheduler unit 1708 is configured to track state information related to the various tasks managed by the scheduler unit 1708. The state may indicate which general processing cluster 1722 a task is assigned to, whether the task is active or inactive, a priority level associated with the task, and so forth. The scheduler unit 1708 manages the execution of a plurality of tasks on the one or more general processing clusters 1722.

The scheduler unit 1708 is coupled to a work distribution unit 1710 that is configured to dispatch tasks for execution on the general processing clusters 1722. The work distribution unit 1710 may track a number of scheduled tasks received from the scheduler unit 1708. In an embodiment, the work distribution unit 1710 manages a pending task pool and an active task pool for each of the general processing clusters 1722. The pending task pool may comprise a number of slots (e.g., 32 slots) that contain tasks assigned to be processed by a particular general processing cluster 1722. The active task pool may comprise a number of slots (e.g., 4 slots) for tasks that are actively being processed by the general processing clusters 1722. As a general processing cluster 1722 finishes the execution of a task, that task is evicted from the active task pool for the general processing cluster 1722 and one of the other tasks from the pending task pool is selected and scheduled for execution on the general processing cluster 1722. If an active task has been idle on the general processing cluster 1722, such as while waiting for a data dependency to be resolved, then the active task may be evicted from the general processing cluster 1722 and returned to the pending task pool while another task in the pending task pool is selected and scheduled for execution on the general processing cluster 1722.

The work distribution unit 1710 communicates with the one or more general processing clusters 1722 via crossbar 1714. The crossbar 1714 is an interconnect network that couples many of the units of the parallel processing unit 1702 to other units of the parallel processing unit 1702. For example, the crossbar 1714 may be configured to couple the work distribution unit 1710 to a particular general processing cluster 1722. Although not shown explicitly, one or more other units of the parallel processing unit 1702 may also be connected to the crossbar 1714 via the hub 1712.

The tasks are managed by the scheduler unit 1708 and dispatched to a general processing cluster 1722 by the work distribution unit 1710. The general processing cluster 1722 is configured to process the task and generate results. The results may be consumed by other tasks within the general processing cluster 1722, routed to a different general processing cluster 1722 via the crossbar 1714, or stored in the memory 1720. The results can be written to the memory 1720 via the memory partition unit 1724 modules, which implement a memory interface for reading and writing data to/from the memory 1720. The results can be transmitted to another parallel processing unit 1702 or CPU via the NVLink 1716. In an embodiment, the parallel processing unit 1702 includes a number U of memory partition unit 1724 modules that is equal to the number of separate and distinct memory 1720 devices coupled to the parallel processing unit 1702.

In an embodiment, a host processor executes a driver kernel that implements an application programming interface (API) that enables one or more applications executing on the host processor to schedule operations for execution on the parallel processing unit 1702. In an embodiment, multiple compute applications are simultaneously executed by the parallel processing unit 1702 and the parallel processing unit 1702 provides isolation, quality of service (QoS), and independent address spaces for the multiple compute applications. An application may generate instructions (e.g., API calls) that cause the driver kernel to generate one or more tasks for execution by the parallel processing unit 1702. The driver kernel outputs tasks to one or more streams being processed by the parallel processing unit 1702. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory.

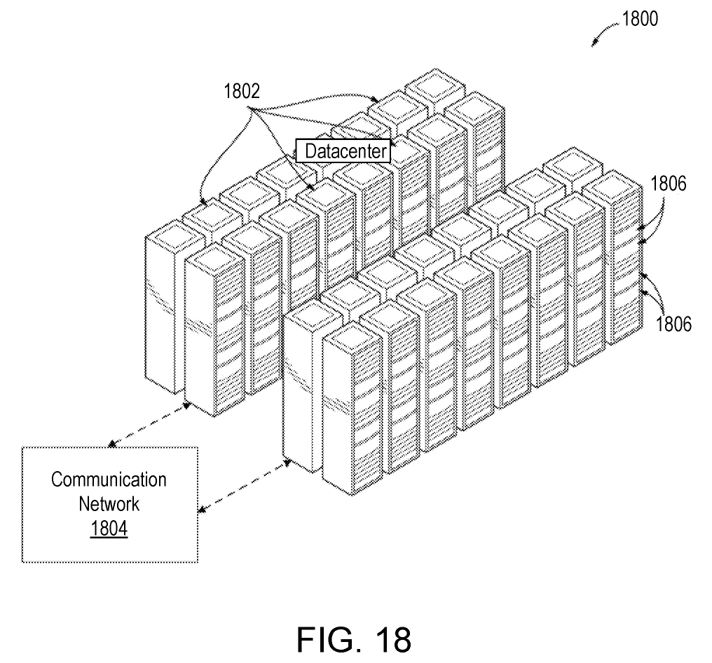

FIG. 18 illustrates an example of an architecture 1800 in which a bridge removal tool may be utilized in accordance with at least some embodiments of the present disclosure. The network architecture 1800 may include additional components and functionalities. For example, the network architecture 1800 may include, without limitation, additional processing units, specialized accelerators (such as Tensor Processing Units or TPUs), enhanced security modules, and redundant power supplies.

The inclusion of these elements may be intended to ensure that the network architecture 1800 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 1800.

The communication network 1804 of FIG. 18 may communicably couple the data center 1802 with network device(s) 1806 and other external devices for data exchange and connectivity. Examples of the communication network 1804 that may be used to connect the data center 1802 and the network device(s) 1806 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 1804 to incorporate multiple network types and configurations may allow the data center 1802 to adapt to diverse application needs, from general data communication to specialized HPC tasks. As described herein, the communication network 1804 may leverage various optical components to establish communication links (e.g., communicably couple) between components in the architecture 1800. As such, the communication network 1804 may include various optical devices, transceivers, modules, and/or the like that are configured to generate optical signals (e.g., provide optical transmitter functionality) and/or receive optical signals (e.g., provide optical receiver functionality).

The network device(s) 1806 may include a variety of computing devices capable of transmitting and receiving signals over the communication network 1804. The network device(s) 1806 may range from personal computing devices to complex server configurations. Examples include Personal Computers (PCs), laptops, tablets, smartphones, and servers. The network device(s) 1806 may facilitate user interactions with the data center 1802, allowing for data input, retrieval, and processing from remote locations. In addition to individual computing devices, the network device(s) 1806 may also include collections of servers or additional data centers. For instance, these could be other data centers similar to or the same as data center 1802. Such an interconnection may allow for the formation of a distributed computing environment for improved redundancy, load balancing, and disaster recovery capabilities. By linking multiple data centers, the network architecture 1800 may leverage geographically dispersed resources.

The communication network 1804 may communicably couple the data center 1802 with network device(s) 1806 and other external devices for data exchange and connectivity.

Each type of network offers specific advantages tailored to different operational requirements. For instance, an IP network or Ethernet network may provide widespread compatibility and ease of integration, supporting various protocols and applications across the data center 1802 and the network device(s) 1806 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

In one non-limiting example, the above-described properties may be achieved with inventive concepts by using InfiniBand (TB) transport and wire protocols. InfiniBand, which underpins state-of-the-art RDMA operations, comprises an all-hardware network transport used to connect supercomputers. InfiniBand has the potential to serve disaggregation traffic in that IB transport provides a reliable pipeline that also maintains in order delivery and, when combined with InfiniBand wire protocol and IB switches, end-to-end QoS and latency guarantees are provided even when the traffic needs to cross several switching layers (e.g., network switches). IB round-trip time (RTT) latency with one switching layer is in the area of 1 us, which is an acceptable latency given a comparison to a dedicated circuit network to perform the same task. In addition, IB NICs typically support the highest transceiver speeds in the industry. One current host attachment approach of IB NICs follows the traditional Direct Memory Access (DMA) engine-assisted integration with an OS-network stack (though many tasks have been offloaded in hardware).

The network device(s) 1806 may include a variety of computing devices capable of sending and receiving signals over the communication network 1804. The network device(s) 1806 can range from personal computing devices to complex server configurations. Examples include Personal Computers (PCs), laptops, tablets, smartphones, and servers. The network device(s) 1806 may facilitate user interactions with the data center 1802, allowing for data input, retrieval, and processing from remote locations. In addition to individual computing devices, the network device(s) 1806 may also include collections of servers or additional data centers. For instance, these could be other data centers similar to or the same as data center 1802. Such an interconnection may allow for the formation of a distributed computing environment for improved redundancy, load balancing, and disaster recovery capabilities. By linking multiple data centers, the data center architecture 1800 can leverage geographically dispersed resources, optimizing performance and ensuring high availability.

The one or more network devices 1806 may include one or more of Personal Computer (PC), a laptop, a tablet, a smartphone, a server, a collection of servers, and/or any suitable computing device for sending and receiving signals over the communication network 1804. In at least one example embodiment, the one or more network devices 1806 correspond to another data center, similar to or the same as data center 1802.

As noted above, the data center 1802 and/or the network device(s) 1806 may include storage devices and/or processing circuitry for carrying out computing tasks, for example, tasks associated with controlling the flow of data internally and/or over the communication network 1804.

In addition, although not explicitly shown, it should be appreciated that the data center 1802 and network device(s) 1806 may include one or more communication interfaces for facilitating wired and/or wireless communication between one another and other unillustrated elements of the data center environment 1800. These communication interfaces may include a variety of technologies, including but not limited to Ethernet ports, fiber optic connections, Wi-Fi® transceivers, Bluetooth® modules, and cellular communication modules for integration and interoperability among the various components within the data center environment 1800. Furthermore, it should be understood that the data center environment 1800 may include additional components and functionalities within the scope of the present disclosure. These components may comprise, without limitation, additional processing units, specialized accelerators (such as Tensor Processing Units or TPUs), enhanced security modules, and redundant power supplies. The inclusion of these elements is intended to ensure that the data center environment 1800 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the data center environment 1800.

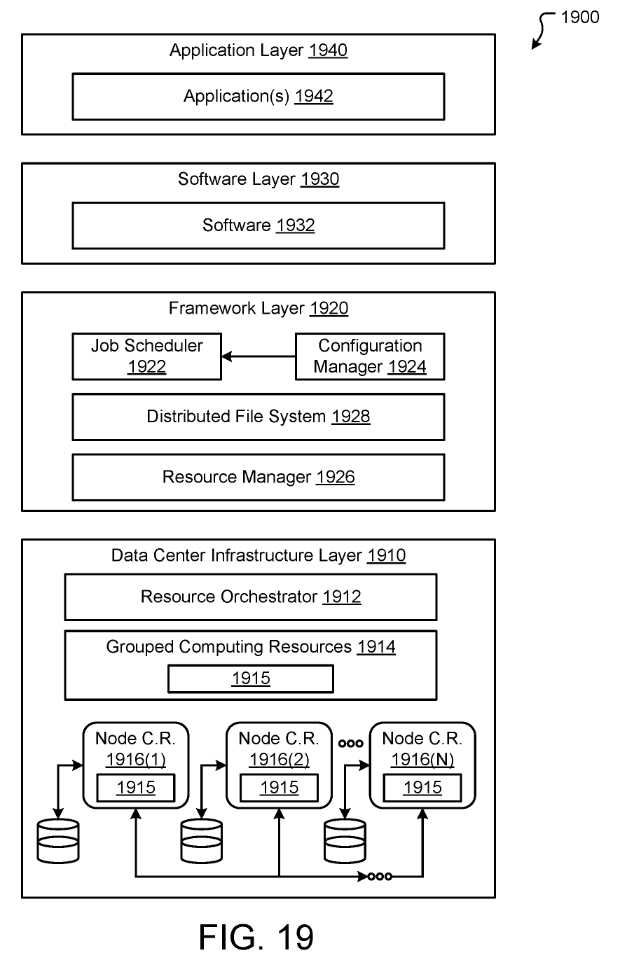

FIG. 19 illustrates additional details of data center layers 1900 and further corresponds to an environment in which a bridge removal tool may be utilized. FIG. 19 specifically illustrates an example data center 1900, in which at least one embodiment may be used. In at least one embodiment, data center 1900 includes a data center infrastructure layer 1910, a framework layer 1920, a software layer 1930 and an application layer 1940.

In at least one embodiment, as shown in FIG. 19, data center infrastructure layer 1910 may include a resource orchestrator 1912, grouped computing resources 1914, and node computing resources (“node C.R.s”) 1916(1)-1916(N), where “N” represents a positive integer (which may be a different integer “N” than used in other figures). In at least one embodiment, node C.R.s 1916(1)-1916(N) may include, but are not limited to, any number of central processing units (“CPUs”) or other processors (including accelerators, field programmable gate arrays (FPGAs), graphics processors, etc.), memory storage devices 1918(1)-1918(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 1916(1)-1916(N) may be a server having one or more of above-mentioned computing resources.

In at least one embodiment, grouped computing resources 1914 may include separate groupings of node C.R.s housed within one or more racks (not shown), or many racks housed in data centers at various geographical locations (also not shown). In at least one embodiment, separate groupings of node C.R.s within grouped computing resources 1914 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1912 may configure or otherwise control one or more node C.R.s 1916(1)-1916(N) and/or grouped computing resources 1914. In at least one embodiment, resource orchestrator 1912 may include a software design infrastructure (“SDI”) management entity for data center 1900. In at least one embodiment, resource orchestrator 1912 may include hardware, software or some combination thereof.

In at least one embodiment, as shown in FIG. 19, framework layer 1920 includes a job scheduler 1922, a configuration manager 1924, a resource manager 1926 and a distributed file system 1928. In at least one embodiment, framework layer 1920 may include a framework to support software 1932 of software layer 1930 and/or one or more application(s) 1942 of application layer 1940. In at least one embodiment, software 1932 or application(s) 1942 may respectively include web-based service software or applications, such as those provided by Amazon Web Services, Google Cloud and Microsoft Azure. In at least one embodiment, framework layer 1920 may be, but is not limited to, a type of free and open-source software web application framework such as Apache Spark™ (hereinafter “Spark”) that may use distributed file system 1928 for large-scale data processing (e.g., “big data”). In at least one embodiment, job scheduler 1922 may include a Spark driver to facilitate scheduling of workloads supported by various layers of data center 1900. In at least one embodiment, configuration manager 1924 may be capable of configuring different layers such as software layer 1930 and framework layer 1920 including Spark and distributed file system 1928 for supporting large-scale data processing. In at least one embodiment, resource manager 1926 may be capable of managing clustered or grouped computing resources mapped to or allocated for support of distributed file system 1928 and job scheduler 1922. In at least one embodiment, clustered or grouped computing resources may include grouped computing resources 1914 at data center infrastructure layer 1910. In at least one embodiment, resource manager 1926 may coordinate with resource orchestrator 1912 to manage these mapped or allocated computing resources.

In at least one embodiment, software 1932 included in software layer 1930 may include software used by at least portions of node C.R.s 1916(1)-1916(N), grouped computing resources 1914, and/or distributed file system 1928 of framework layer 1920. In at least one embodiment, one or more types of software may include, but are not limited to, Internet web page search software, e-mail virus scan software, database software, and streaming video content software.

In at least one embodiment, application(s) 1942 included in application layer 1940 may include one or more types of applications used by at least portions of node C.R.s 1916(1)-1916(N), grouped computing resources 1914, and/or distributed file system 1928 of framework layer 1920. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1924, resource manager 1926, and resource orchestrator 1912 may implement any number and type of self-modifying actions based on any amount and type of data acquired in any technically feasible fashion. In at least one embodiment, self-modifying actions may relieve a data center operator of data center 1900 from making possibly bad configuration decisions and possibly avoiding underused and/or poor performing portions of a data center.

In at least one embodiment, data center 1900 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 1900. In at least one embodiment, trained machine learning models corresponding to one or more neural networks may be used to infer or predict information using resources described above with respect to data center 1900 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

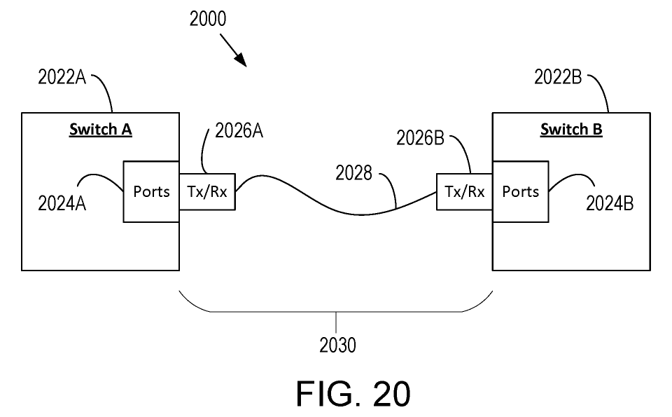

FIG. 20 illustrates additional details of the components on which a bridge removal tool may be used. While aspects of a bridge removal tool are mechanical, it should be appreciated that the circuit boards from which a bridge board is being removed may correspond to circuit boards used within switches 2022A, 2022B without departing from the scope of the present disclosure.

FIG. 20 provides a block diagram that schematically illustrates an optical communication system 2000, in accordance with an embodiment of the present disclosure.

Communication ports 2024A and 2024B of two switches 2022A and 2022B, also herein termed “switch A” 2022A and “switch B,” 2022B are connected by an active optical cable 2030. Cable 2030 may include a ribbon of one or more optical fibers 2028, terminated at each end by generally similar transceiver modules 2026A and 2026B (denoted Tx/Rx in FIG. 20). The terms “transceiver module” and “connector module” may be used interchangeably without departing from the scope of the present disclosure.

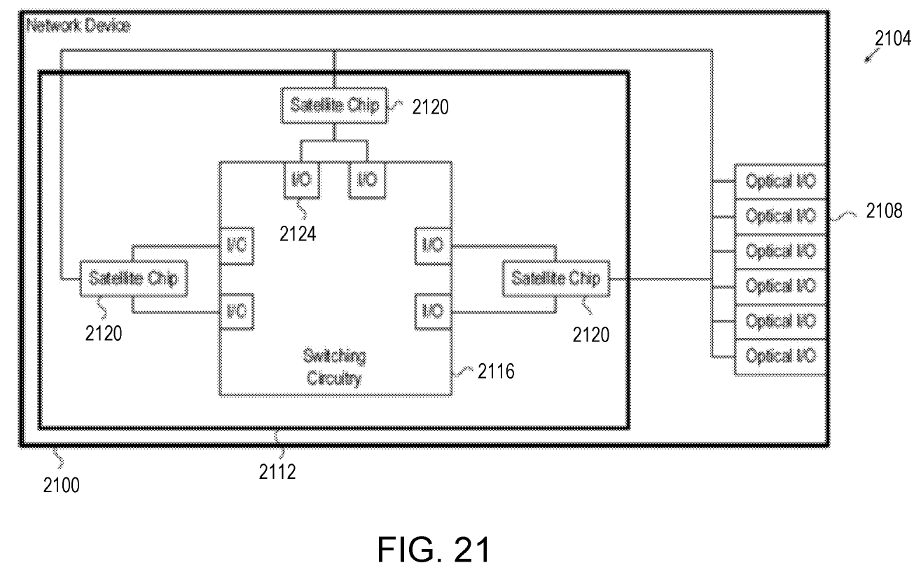

FIG. 21 provides a block diagram of a network device 2100 that may be provided or may include a Multichip-module (MCM) assembly. The bridge removal tool of the present disclosure may be particularly well-suited for servicing such network devices in that the bridge removal tool may be designed to remove one or more high-density chips or packages from a larger system without damaging gold fingers or connectors.

FIG. 21 specifically illustrates that different chips may constitute a co-packaged Networking Device are assembled on a single substrate in what is typically called the MCM assembly 2012. The MCM assembly 2112 can include a switching circuitry 2116 surrounded by peripheral or satellite chips 2120. In some embodiments, the switching circuitry 2116 and surrounding satellite chips 2120 are all mounted on a common substrate, although such a configuration is not required. The MCM assembly 2112 may be provided in a larger housing of the networking device 2100, positioned behind the front panel 2104. The switching circuitry 2116 may include one or more core digital Application Specific Integrated Circuits (ASICs), CPUs, GPUs, microprocessors, FPGAs, combinations thereof, and the like. The switching circuitry 2116 may include a number of input ports and/or output ports 2128. The Input/Output (I/O) ports 2124 may include electrical ports and/or optical ports. Additionally, the switching circuitry 2116 may include a combination of electrical blocks and optical blocks. The electrical blocks of the switching circuitry 2116 may include a number of electrical switches that are configured to route signals in an electrical domain. The optical blocks of the switching circuitry 2116 may include a number of optical components that are configured to generate, detect and route signals in an optical domain. The MCM assembly 2112, in some embodiments, may concern or include multiple satellite chips 2120 that are assembled on the same substrate as the switching circuitry 2116. In some embodiments, a configuration of the optical block(s) and a configuration of the electrical block(s) depends (e.g., is based on) on the number of optical ports in the I/O ports 2124.

As discussed above, optical I/Os 2108, which may also be referred to as optical connectors, are placed at the front panel 2104. As mentioned above, connectivity between the MCM assembly 2112 and optical I/Os 2108 may be transferred to the front panel 2104 through optical fibers. This connection may be made directly with an optical I/O 2124 of the switching circuitry or may be made with one or more of the satellite chips 2120. The connection is often made with one or more of the satellite chips 2120 because the satellite chips 2120 may include the electro-optic converters and, possibly, the SERDES to natively support the connection. The satellite chips 2120 may include one or more of a DSP processor, driver, trans-impedance amplifier, laser, modulator, photodiode, serializer-deserializer, or the like.

Packaging techniques for integrated circuit chips have developed such that modern central processing unit (“CPU”) and graphics processing unit (“GPU”) packages include a substrate on which the integrated circuit die is mounted. A rectangular grid or array of connecting points is typically provided on the bottom side of the substrate to connect the circuitry of the integrated circuit die with the circuitry of a host system printed circuit board (“PCB”) through conductors inside the substrate. Examples of such grids or arrays of connecting points include pin grid arrays (“PGA”), ball grid arrays (“BGA”), land grid arrays (“LGA”), and the like. A substrate has a larger area than does an integrated circuit die, so inclusion of a substrate in the chip package makes more space available to accommodate the relatively large PGA pins, BGA solder balls, or LGA contact pads that must be placed on the package.

In the packaging of integrated circuit (IC) chips, various packaging schemes are employed, including traditional two-dimensional (2D) integrated circuit (IC) packages as well as the more recently introduced 2.5D IC and 3D IC packages. In 2D IC packages, multiple chips are mounted on a printed circuit board, where high-performance logic, lower-performance logic, memory, and analog/RF functions, and other functional elements are presented as discrete devices in separate chip packages. By contrast, in 2.5D ICs and 3D IC packages, multiple IC chips are mounted on a silicon interposer instead of a conventional package substrate. The silicon interposer, which is typically a silicon wafer, allows very small and high-density conductive traces to be formed between the multiple IC chips because the fabrication processes used to form the conductive traces are the same processes used to form the metal interconnects in the metallization layers of a silicon chip.

Compared to 2.5D IC packages and 3D IC packages, a circuit board with individually packaged chips, such as a 2D IC package, has numerous disadvantages. For example, a 2D IC package is generally larger, heavier, consumes more power, and, because the signals propagate relatively slowly across the circuit board from one chip to another, is slower than an equivalent 2.5D or 3D IC package. Furthermore, a 2D IC package has more possible points of failure, given that the soldered joints on the circuit board are more likely to fail than the electrical connections formed within an interposer. That said, troubleshooting a 2D IC package after the different chips have been mounted on the circuit board is relatively straightforward. In particular, the conductive traces carrying I/O signals between the various chips on the circuit board are easily accessible and therefore can be employed to measure specific I/O signals during troubleshooting.

By contrast, troubleshooting a 2.5D or 3D IC package is far more problematic because the I/O signals transmitted between the different chips typically are embedded in the silicon interposer and are not physically accessible. Furthermore, because 2.5D and 3D IC packages are high-bandwidth and are quite dense, such packages can benefit from removal with a bridge removal tool in accordance with at least some embodiments of the present disclosure.

Additionally, the bridge removal tool may be utilized in systems incorporating die-to-die interconnects within the package and across multiple packages or discrete dies mounted on a printed circuit board (PCB). These die-to-die interconnects enable communication between discrete chips or chiplets using high-speed serial links such as PCIe, NVLink, or CXL. The PCB interconnects must address signal integrity, power delivery, and routing challenges while accommodating various packaging formats, including organic substrates, silicon interposers, stacked HBM, and optical interconnects.

At the system level, multiple PCBs or compute modules are interconnected within a rack using high-bandwidth server-class interconnects for efficient node-to-node communication. Data center-level connectivity is enabled throughout the data center using high-performance fabrics such as Ethernet, InfiniBand, or custom optical networks, forming a distributed computing infrastructure. This scalable, hierarchical interconnect architecture—from on-die, chiplet, and silicon interposer interconnects, to 3D die stacking, 3D-stacked HBM, chiplet-based optical interconnects, and die-to-die interconnects—enables modular, power-efficient, and high-performance computing systems suitable for AI, HPC, and next-generation data-intensive applications.

A die-to-die interconnect system enables high-speed communication between two or more integrated circuit (IC) dies, either mounted on a common interposer or directly on a printed circuit board (PCB). These architectures support advanced packaging solutions for heterogeneous integration, chiplet-based designs, and system-in-package (SiP) implementations.

In the case of an interposer-based configuration, the dies are placed on a passive or active interposer substrate, which provides fine-pitch routing and high-density signal redistribution between the dies. The interposer may be formed from silicon, glass, or organic material, and may include features such as redistribution layers (RDLs), through-silicon vias (TSVs), or through-glass vias (TGVs). This approach allows for short interconnect lengths, reduced parasitics, and improved signal integrity.

In the case of a PCB-based configuration, the dies are mounted directly onto a high-density PCB that provides electrical connectivity between them. The PCB may be a high-performance organic laminate or other substrate material designed to support fine-pitch routing and high-frequency signal propagation. Interconnects between dies may be implemented using traces, vias, or embedded structures, and may be supplemented by solder bumps, wire bonds, or advanced packaging interconnect techniques such as micro-bumps or copper pillars.

In either configuration, the die-to-die interconnect may support electrical signaling, optical signaling, or a combination thereof. Optical interconnects may utilize embedded waveguides, photonic integrated components, or optical fibers coupled through grating couplers or edge couplers to provide low-latency, high-bandwidth communication. Electrical interconnects may be designed to support differential signaling, power delivery, and high-speed interfaces such as PCIe, SerDes, or custom protocols.

These architectures offer benefits such as modularity, performance scalability, improved power efficiency, and the ability to integrate dies fabricated using different technology nodes or process types (e.g., logic, memory, analog, photonic). They are particularly suited for high-performance computing, AI accelerators, networking devices, and co-packaged optics systems.

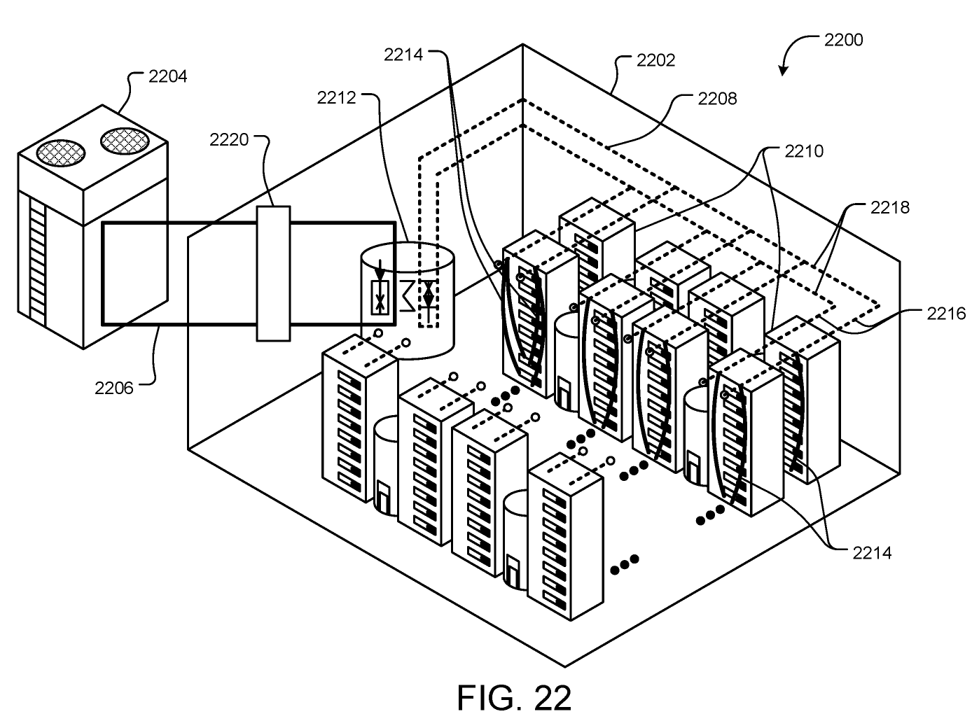

It should also be appreciated that embodiments of the present disclosure may be utilized in removing bridge boards from component housings 304 that are cooled with at least one of liquid cooling and/or air flow. Some examples of a component housing 304 are shown to include air vents to help cool the circuit boards contained in computing component assemblies 302. FIG. 22 illustrates an example of a data center 2200 in which a bridge removal tool may be utilized.

In at least one embodiment, an example data center 2200 can be utilized as illustrated in FIG. 22, which has a cooling system subject to improvements described herein. In at least one embodiment, a data center 2200 may be one or more rooms 2202 having racks 2210 and auxiliary equipment to house one or more servers on one or more server trays. In at least one embodiment, a data center 2200 is supported by a cooling tower 2204 located external to a data center 2200. In at least one embodiment, a cooling tower 2204 dissipates heat from within a data center 2200 by acting on a primary cooling loop 2206. In at least one embodiment, a cooling distribution unit (CDU) 2212 is used between a primary cooling loop 2206 and a second or secondary cooling loop 2208 to enable absorption of heat from a second or secondary cooling loop 2208 to a primary cooling loop 2206. In at least one embodiment, a secondary cooling loop 2208 can access various plumbing into a server tray as required, in an aspect. In at least one embodiment, loops 2206, 2208 are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop 2206, 2208. In at least one embodiment, one or more coolant pumps may be used to maintain pressure differences within coolant loops 2206, 2208 to enable movement of coolant according to temperature sensors in various locations, including in a room, in one or more racks 2210, and/or in server boxes or server trays within one or more racks 2210.

In at least one embodiment, coolant in a primary cooling loop 2206 and in a secondary cooling loop 2208 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 2210. In at least one embodiment, a CDU 2212 is capable of sophisticated control of coolants, independently or concurrently, within provided coolant loops 2206, 2208. In at least one embodiment, a CDU may be adapted to control flow rate of coolant so that coolant is appropriately distributed to absorbed heat generated within associated racks 2210. In at least one embodiment, more flexible tubing 2214 is provided from a secondary cooling loop 2208 to enter each server tray to provide coolant to electrical and/or computing components therein.

The heat transfer fluid generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

In at least one embodiment, tubing 2218 that forms part of a secondary cooling loop 2208 may be referred to as room manifolds. Separately, in at least one embodiment, further tubing 2216 may extend from row manifold tubing 2218 and may also be part of a secondary cooling loop 2208 but may be referred to as row manifolds. In at least one embodiment, coolant tubing 2214 enters racks as part of a secondary cooling loop 2208 but may be referred to as rack cooling manifold within one or more racks. In at least one embodiment, row manifolds 2216 extend to all racks along a row in a data center 2200. In at least one embodiment, plumbing of a secondary cooling loop 2208, including coolant manifolds 2218, 2216, and 2214 may be improved by at least one embodiment herein. In at least one embodiment, a chiller 2220 may be provided in a primary cooling loop within data center 2202 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 2210 may be transferred to a coolant exiting one or more racks 2210 via flexible tubing of a row manifold 2214 of a second cooling loop 2208. In at least one embodiment, second coolant (in a secondary cooling loop 2208) from a CDU 2212, for cooling provided racks 2210, moves towards one or more racks 2210 via provided tubing. In at least one embodiment, second coolant from a CDU 2212 passes from on one side of a room manifold having tubing 2218, to one side of a rack 2210 via a row manifold 2216, and through one side of a server tray via different tubing 2214. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 2210 comes out of different side (such as exiting side) of tubing 2214 and moves to a parallel, but also exiting side of a row manifold 2216. In at least one embodiment, from a row manifold 2216, spent second coolant moves in a parallel portion of a room manifold 2218 and is going in an opposite direction than incoming second coolant (which may also be renewed second coolant), and towards a CDU 2212.

In at least one embodiment, spent second coolant exchanges its heat with a primary coolant in a primary cooling loop 2206 via a CDU 2212. In at least one embodiment, spent second coolant may be renewed (such as relatively cooled when compared to a temperature at a spent second coolant stage) and ready to be cycled back to through a second cooling loop 2208 to one or more computing components. In at least one embodiment, various flow and temperature control features in a CDU 2212 enable control of heat exchanged from spent second coolant or flow of second coolant in and out of a CDU 2212. In at least one embodiment, a CDU 2212 may be also able to control a flow of primary coolant in primary cooling loop 2206.

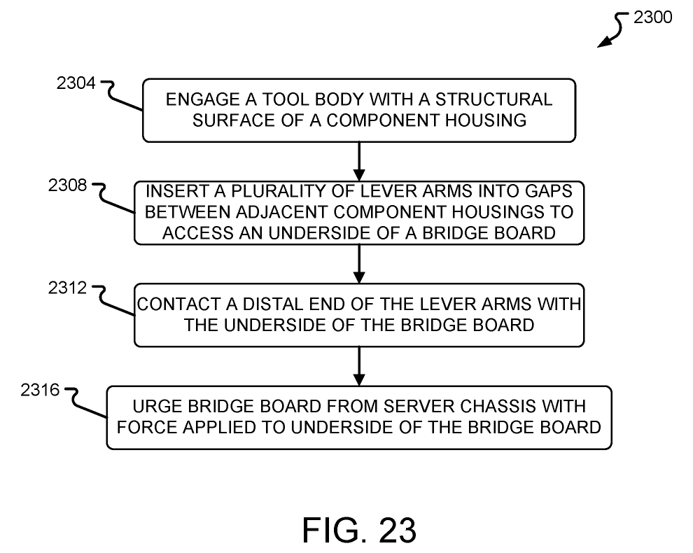

FIG. 23 illustrates an example of a method 2300 of utilizing a bridge removal tool in accordance with at least some embodiments of the present disclosure. The method 2300 is shown to include a first step of engaging a tool body with a structural surface of a component housing (step 2304). The component housing may be a part of a computing component assembly 302, which may include at least one circuit board.

The method 2300 may further include inserting a plurality of lever arms into gaps between adjacent component housings to access an underside of a bridge board (step 2308). In some embodiments, at least two lever arms are inserted into at least two different gaps such that the lever arms are positioned at least partially underneath the bridge board.

The method 2300 may further include contacting a distal end of each lever arm with the underside of the bridge board (step 2312). In some embodiments, each distal end of each lever arm is configured to simultaneously contact the underside surface of the bridge board such that forces exerted on the bridge board are evenly and safely distributed across the bridge board.

The method 2300 may then include urging the bridge board from the chassis with one or more forces applied to the underside of the bridge board (step 2316). In some embodiments, the force(s) applied to the underside of the bridge board correspond to upward forces, and such forces may be applied by the distal end(s) of the lever arms contacting the underside of the bridge board.

Within this disclosure, different entities (which may variously be referred to as "units," "circuits," other components, etc.) may be described or claimed as "configured" to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be "configured to" perform some task even if the structure is not currently being operated. A "credit distribution circuit configured to distribute credits to a plurality of processor cores" is intended to cover, for example, an integrated circuit that has circuitry that performs this function during operation, even if the integrated circuit in question is not currently being used (e.g., a power supply is not connected to it). Thus, an entity described or recited as "configured to" perform some task refers to something physical, such as a device, circuit, memory storing program instructions executable to implement the task, etc. This phrase is not used herein to refer to something intangible.

The term "configured to" is not intended to mean "configurable to." An unprogrammed FPGA, for example, would not be considered to be "configured to" perform some specific function, although it may be "configurable to" perform that function after programming.

Reciting in the appended claims that a structure is "configured to" perform one or more tasks is expressly intended not to invoke 35 U.S.C. § 112(f) for that claim element. Accordingly, claims in this application that do not otherwise include the "means for" [performing a function] construct should not be interpreted under 35 U.S.C § 112(f).

As used herein, the terms "first," "second," etc. are used as labels for nouns that they precede, and do not imply any type of ordering (e.g., spatial, temporal, logical, etc.), unless stated otherwise. For example, in a register file having eight registers, the terms "first register" and "second register" can be used to refer to any two of the eight registers, and not, for example, just logical registers 0 and 1.

When used in the claims, the term "or" is used as an inclusive or and not as an exclusive or. For example, the phrase "at least one of x, y, or z" means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Having thus described illustrative embodiments in detail, it will be apparent that modifications and variations are possible without departing from the scope of the disclosure as claimed. The scope of inventive subject matter is not limited to the depicted embodiments but is rather set forth in the following Claims.

What is claimed is:

1. A tool, comprising:
a body having a pivot surface; and
a plurality of lever arms arranged linearly along the pivot surface, wherein each of the plurality of lever arms is formed such that the body forms an acute angle of engagement with a computing component assembly by contacting a structural surface of a component housing in which at least one circuit board is contained.

2. The tool of claim 1, wherein, in a deployed configuration, (a) the pivot surface contacts a structural surface of the component housing, (b) a distal end of each of the plurality of lever arms contacts an underside of a bridge board mounted parallel to the structural surface of the component housing, and (c) an arc of each of the plurality of lever arms contacts an edge of the bridge board.

3. The tool of claim 2, wherein at least one of the plurality of lever arms extends from the pivot surface to a distal end and wherein an interior angle between the at least one of the plurality of lever arms and the pivot surface is obtuse such that the body is configured to form an acute angle relative to the structural surface when the at least one of the plurality of lever arms is deployed.

4. The tool of claim 1, wherein at least one of the plurality of lever arms comprises a distal end comprising a rectangular shape with a valley formed therein.

5. The tool of claim 1, wherein the body is formed such that a number of lever arms deployed from the body is configurable.

6. The tool of claim 1, wherein each of the plurality of lever arms are configured to extend from a corresponding slot in the body.

7. The tool of claim 1, wherein the body comprises a tool body length, wherein at least one lever arm in the plurality of lever arms comprises a lever arm length, and wherein the tool body length is at least twice the lever arm length.

8. An apparatus, comprising:
a body comprising a pivot surface that extends along a first end of the body; and
a plurality of lever arms arranged linearly along the pivot surface and that project from the pivot surface such that a geometry of the pivot surface and the plurality of lever arms facilitate removal of a bridge board from a computing component assembly by causing at least one of the plurality of lever arms to contact an underside of the bridge board.

9. The apparatus of claim 8, wherein the geometry of the pivot surface and the plurality of lever arms form an arc between the pivot surface and a distal end of each of the plurality of lever arms.

10. The apparatus of claim 8, wherein at least some of the plurality of lever arms are extendible from a corresponding slot formed in the body.

11. The apparatus of claim 8, wherein a number and positions of the plurality of lever arms are reconfigurable among a plurality of slots.

12. The apparatus of claim 8, wherein the plurality of lever arms comprise at least two lever arms.

13. The apparatus of claim 8, wherein the plurality of lever arms comprise at least four lever arms.

14. The apparatus of claim 8, wherein each of the plurality of lever arms comprise a distal end that physically contacts the underside of the bridge board.

15. The apparatus of claim 8, wherein the computing component assembly comprises at least one component housing and wherein the bridge board is provided over the at least one component housing.

16. The apparatus of claim 15, wherein each of the plurality of lever arms extend into gaps between adjacent component housings to access the underside of the bridge board.

17. The apparatus of claim 8, wherein the computing component assembly is provided in a chassis.

18. The apparatus of claim 8, wherein the pivot surface engages at least one component housing in the computing component assembly.

19. The apparatus of claim 8, wherein the plurality of lever arms apply an upward force to the bridge board in response to rotation of the body about the pivot surface.

20. The apparatus of claim 8, wherein each of the plurality of lever arms comprise a distal end having a rectangular shape with a valley formed therein.

21. The apparatus of claim 8, wherein the body comprises a tool body length, wherein at least one lever arm in the plurality of lever arms comprises a lever arm length, and wherein the tool body length is at least twice the lever arm length.

22. A bridge board removal process, comprising:
(a) pivotably engaging a tool body with a structural surface of at least one component housing, wherein the tool body forms an acute angle relative to the structural surface;
(b) inserting a plurality of lever arms into gaps between adjacent component housings to access an underside of the bridge board; and
(c) contacting a distal end of the lever arms with the underside of the bridge board to urge the bridge board from the at least one component housing.

23. The bridge board removal process of claim 22, wherein the tool body comprises a tool body length, wherein at least one lever arm in the plurality of lever arms comprises a lever arm length, and wherein the tool body length is at least twice the lever arm length.

24. The bridge board removal process of claim 22, wherein the tool body comprises a pivot surface that contacts at least one of the plurality of component housings and creates a leverage point where the pivot surface contacts the structural surface to enable the distal end to provide an upward force on the underside of the bridge board while preserving an integrity of a circuit board contained within the at least one component housing.
